(19) United States
(12) Patent Application Publication
(10) Pub. No.: US 2008/0251913 A1
(43) Pub. Date: Oct. 16, 2008

(54) SEMICONDUCTOR DEVICE INCLUDING WIRING SUBSTRATE HAVING ELEMENT MOUNTING SURFACE COATED BY RESIN LAYER

(75) Inventor: Teruji INOMATA, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 11/851,400

(22) Filed: Sep. 7, 2007

(30) Foreign Application Priority Data
Sep. 14, 2006 (JP) 2006-249559

(51) Int. Cl. H01L 23/48

(52) U.S. Cl. 257/737; 257/778; 257/E23.01

(57) ABSTRACT

In one embodiment of the present invention, there is provided a semiconductor device including a first semiconductor element mounted, through flip-chip bonding, on the element mounting surface of a first wiring substrate, and a resin layer that coats substantially the entire element mounting surface of the first wiring substrate. The first semiconductor element has two opposite surfaces. One surface faces the element mounting surface of the first wiring substrate, and the other surface is not coated by the resin layer.

### BACKGROUND OF THE INVENTION

1. Field of the Invention

The present invention relates to a semiconductor device, and more particularly to a semiconductor device constituting a thin type semiconductor package, a package-on-package structure, and a package-on-chip structure where a semiconductor package and a semiconductor chip are stacked.

2. Description of the Related Art

As prior arts relating to the flip-chip type semiconductor device, there are semiconductor devices described in Japanese Patent Laid-Open Nos. 2006-108460, 2000-299414, 2000-260820, 5-283455, 2004-260138 and “High Speed Characteristic Such That Instantaneous Chance Is Not Escaped” [online] [Retrieve Jul. 18, 2006] Internet <URL: http://www.canon-sales.co.jp/camera/ixyd/60/feature04.html>.

In Japanese Patent Laid-Open No. 2006-108460, it is described that, in sealing the part between a semiconductor chip and a wiring substrate by underfill resin, stress takes place resulting from thermal expansion coefficient difference between the semiconductor element and the underfill resin and the wiring substrate so that the wiring substrate warps toward the semiconductor element side. Moreover, in the above Literature, a belt-shaped elastic body is embedded within a flip-chip connection wiring substrate to thereby suppress warp.

In Japanese Patent Laid-Open Nos. 2000-299414, 2000-260820, there is described a structure in which an underfill material is filled within a gap between an organic substrate and a semiconductor chip, and its side part is sealed by fillet material. Further, in Japanese Patent Laid-Open No. 2000-299414, the underfill material is sealed under a specific condition to thereby allow stresses applied to the chip surfaces to be uniform. Thus, peeling and crack of the chip can be prevented.

FIG. 13 is a cross sectional view showing the configuration of a semiconductor device corresponding to the devices described in Japanese Patent Laid-Open Nos. 2000-299414, 2000-260820. In FIG. 13, underfill material and fillet material are indicated without distinguishing therebetween.

In the semiconductor device shown in FIG. 13, a semiconductor chip 203 is connected, through flip-chip bonding, by bump electrodes 209, to the chip mounting surface of a package substrate 201. At the region between the package substrate 201 and the semiconductor chip 203 and its side part thereof, an underfill resin 205 is provided. In FIG. 13, external connection electrodes 211 provided on the reverse surface of the chip mounting surface of the package substrate 201 are shown in addition to the configuration of the above Literatures.

In Japanese Patent Laid-Open No. 5-283455, it is described that a specific composition is filled within a gap between chip device and carrier. Moreover, this configuration guarantees that no crack takes place even after excessive heat cycle.

In Japanese Patent Laid-Open No. 2004-260138, there is described a semiconductor device in which a frame-shaped reinforcement material surrounding semiconductor chip is bonded onto a mounting board. In accordance with the above Literature, warp of the mounting board resulting from thermal/mechanical stress during manufacturing process is reduced and strength is increased by the reinforcement material.

Moreover, “High Speed Characteristic Such That Instantaneous Chance Is Not Escaped” [online] [Retrieve Jul. 18, 2006] Internet <URL: http://www.canon-sales.co.jp/camera/ixyd/60/feature04.html> relates to a package including plural chips. In the above Literature, it is considered that the substrate is thickened to thereby suppress package warp.

Further, as the prior art relating to package including plural chips, there is the technology described in “Successive Mass production of Semiconductor Package” [online] Semiconductor Industrial Newspaper dated Jan. 18, 2006 [Retrieve Jul. 18, 2006] Internet <URL: http://www.semicon-news.co.jp/news/htm/sn1673-j.htm>. In the above Literature, there is employed a stacked structure of wire-bonding package.

FIGS. 14(A) and 14(B) are cross sectional views showing the configuration of a semiconductor device corresponding to the device described in “Successive Mass production of Semiconductor Package” [online] Semiconductor Industrial Newspaper dated Jan. 18, 2006 [Retrieve Jul. 18, 2006] Internet <URL: http://www.semicon-news.co.jp/news/htm/sn1673-j.htm>.

In FIG. 14(A), semiconductor chip 203 is mounted on a package substrate 201. Further, the semiconductor chip 203 and the package substrate 201 are connected by bonding wires 231. The semiconductor chip 203 and the bonding wires 231 are sealed by a sealing resin 233, and the entirety of the semiconductor chip 203 is embedded within the sealing resin 233. Moreover, in FIG. 14(B), there is shown a configuration in which a semiconductor package 215 is stacked, through substrate connection electrodes 213, on the upper part of the package substrate 201 of the device of FIG. 14(A).

Here, in the case where attempt is made to apply a semiconductor device to compact portable or mobile electronic equipment, etc. including mobile telephone, miniaturization and realization of thin structure of the entirety of the semiconductor device are required.

However, in the above-described conventional configurations, there was a room in that its warp should be more satisfactorily suppressed while performing realization of thin structure of the package substrate.

As a typical package-on-package structure, there is frequently used a structure as shown in FIG. 15(C). In FIG. 15(C), reference numeral 215 indicates a semiconductor package, and reference numeral 213 indicates a substrate connection electrode.

Moreover, reference numeral 201 indicates a package substrate, reference numeral 203 indicates a semiconductor chip, reference numeral 205 indicates an underfill resin, reference numeral 209 indicates a bump electrode, and reference numeral 211 indicates an external connection electrode.

As typical means for realizing the structure of FIG. 15(C), there is means as described below. First, components such as the package substrate 201 and the semiconductor chip 203, etc. shown in FIG. 15(B) are constituted thereafter to connect the semiconductor package part shown in FIG. 15(A) through the substrate connection electrodes 213.

In this case, for example, in the structure shown in FIG. 15(B), the package substrate 201 warps in a convex form with the chip mounting surface being positioned upwardly by tensile stress of the package substrate 201 taking place resulting from thermal expansion coefficient difference between the semiconductor chip 203 and the package substrate 201, or tensile stress of the underfill resin 205 taking place resulting from thermal expansion coefficient difference between the semiconductor chip 203 and the underfill resin 205.

When warp of such convex part is great, this constitutes obstacle in connecting the semiconductor package part shown in FIG. 15(A) to the package substrate 201.

In view of the above, there is conventionally employed, for the purpose of reducing warp, a method of thickening the package substrate 201 on which the semiconductor chip 203 is mounted, etc. By stacking the semiconductor package 215 through the substrate connection electrodes 213 onto the structure of FIG. 15(B) in which warp has been reduced in this way, there is obtained a structure shown in FIG. 15(C).

However, employment of the method of thickening the package substrate 201 as countermeasure for warp is disadvantageous to realization of thin structure of the entirety of the semiconductor device. This is because since warp quantity of the package substrate 201 is determined by rigidity of the package substrate 201 and rigidity of the semiconductor chip 203, the thickness of the substrate dominant to the rigidity of the package substrate 201 would be increased. For this reason, it was difficult to apply such a method of thickening the substrate to the field for which realization of thin structure of the substrate itself is required. Moreover, in the case where package is stacked, components attachment height becomes large. This constitutes obstacle to realization of thin structure.

Further, as a countermeasure for warp of the package substrate 201, there is also a method of providing a metallic support in addition to the above. In this case, it is impossible to provide substrate connection electrode 213 for connection with semiconductor package 215 at the part in which the metallic support is provided. For this reason, the area of the components becomes large so that mounting density is lowered. Accordingly, this constitutes hindrance to miniaturization of the entirety of the semiconductor device. Further, when the metallic support is thickened for the purpose of maintaining sufficient rigidity for warp suppression, the thickness of the entirety of the device would be increased.

Further, in the technology described in “Successive Mass production of Semiconductor Package” [online] Semiconductor Industrial Newspaper dated Jan. 18, 2006 [Retrieve Jul. 18, 2006] Internet <URL: http://www.semicon-news.co.jp/news/htm/sn1673-j.htm>, as shown in FIGS. 14(A) and 14(B), the semiconductor chip 203 is embedded within the sealing resin 233. For this reason, this leads to increase in the components attachment height. Moreover, in the case where the same number of terminals are provided on the semiconductor chip, since electrical connection between the semiconductor chip and the package substrate is provided by the wire-bonding process, the chip size is enlarged to more degree as compared to the case of the flip-chip connection. For this reason, there will result in enlargement of components.

In addition, in the case of obtaining electrical connection between the package substrate 201 and the semiconductor chip 203 by the wire-bonding process, the number of terminals which can be disposed on the package substrate 201 becomes small as compared to the flip-chip structure (FIG. 13) in addition to the fact that the attachment height is increased. For this reason, in the case where the same number of terminals are provided on the chip, the chip size would be enlarged. Thus, miniaturization of components is prevented.

On the other hand, there are instances where in the case where thin structure of the substrate is only realized, rigidity of the substrate cannot be sufficiently ensured with respect to warp generation factor such as thermal expansion coefficient difference between the semiconductor chip and the substrate and curing contraction of resin in liquid form, etc. For this reason, after assembling of the device is completed, the side of the element mounting surface of the substrate may be curved in convex form so that warp-up is apt to take place. Further, even if the above-described prior arts are used, it is still impossible to satisfy the standard of coplanarity after assembling. There is a fear that yield would be lowered.

In view of the above, an object of invention of this application is to provide a semiconductor device in which warp of semiconductor package is suppressed while realizing thin structure of the semiconductor package so that manufacturing yield has been improved.

### SUMMARY OF THE INVENTION

The inventors have energetically studied with a view to suppressing warp of chip mounting substrate of the semiconductor device on the basis of the above findings. As a result, they have found that resin is provided on substantially the entire element mounting surface of the wiring substrate on which the semiconductor chip is mounted, and the reverse surface of the semiconductor chip is not coated by such resin, thereby making it possible to remarkably reduce warp quantity of the wiring substrate while realizing thin structure of the entirety of the device.

In accordance with the present invention, there is provided a semiconductor device including:

a first wiring substrate;

a first semiconductor element mounted, through flip-chip bonding, on an element mounting surface of the first wiring substrate; and

a resin layer that coats substantially the entire element mounting surface of the first wiring substrate including an area where the first semiconductor element is mounted,

wherein the first semiconductor element has two opposite surfaces, one surface facing the element mounting surface of the first wiring substrate, the other surface being not coated by the resin layer.

In the present invention, substantially the entire surface of the element mounting surface of the first wiring substrate is coated by resin layer. By performing such coating, contraction stress can be produced on substantially the entire surface of the element mounting surface. In the assembling process of the conventional semiconductor devices, warp would take place in a convex form with the element mounting surface being positioned upwardly by substrate contraction stress taking place resulting from thermal expansion coefficient difference between the semiconductor chip and the wiring substrate, or contraction process taking place resulting from thermal expansion coefficient difference between the semiconductor chip and the underfill resin. On the contrary, in the present invention, by the above-described contraction stress, it is possible to produce warp in a concave form with the element mounting surface being positioned upwardly on the first wiring substrate. Thus, warp in convex form is cancelled so that coplanarity can be improved.

Accordingly, in accordance with the present invention, also in the case where the thickness of the wiring substrate is thin, it is possible to securely reduce warp taking place on the resin substrate. For this reason, manufacturing yield can be improved. Moreover, also when the semiconductor device of the present invention is used for stacked package, etc., it is possible to improve yield in stacking process.

In this case, the fact that the resin layer coats substantially the entire surface of the element mounting surface refers to the fact that the resin layer is reached up to the end part of the element mounting surface. In the case where electrodes and the element are bonded on the element mounting surface, the resin layer may coat the entirety of the element mounting surface excluding these bonding parts.

Moreover, the first semiconductor element may be a semiconductor chip having a predetermined element or elements such as transistor, etc., and may further include wiring member for external terminal taking-out purpose at the semiconductor chip. For example, the first semiconductor element may be also semiconductor element in which semiconductor chip is connected through an interposer.

In the case of the semiconductor element in which semiconductor chip is connected through interposer, the first semiconductor element may be of the configuration in which it is connected from the bump electrode to the first wiring substrate through the interposer substrate. In this case, it is preferable that the thickness of the interposer substrate is thin.

It is to be noted that arbitrary combination of these respective configurations, and embodiments in which the expressions of the present invention are changed or modified with respect to the method and device, etc. may be effective as embodiments of the present invention.

As explained above, in accordance with the present invention, thin structure of semiconductor device can be realized, and lowering of the manufacturing yield thereof can be suppressed.

### BRIEF DESCRIPTION OF THE DRAWINGS

FIG. 1 is cross sectional view showing the configuration of semiconductor device in a first embodiment;

FIG. 2 is a plane view showing the configuration of the semiconductor device shown in FIG. 1;

FIG. 3 is a cross sectional view for explaining a method of manufacturing the semiconductor device shown in FIG. 1;

FIG. 4 is a cross sectional view showing the configuration of the semiconductor device of a second embodiment;

FIG. 5 is a plan view showing the configuration of the semiconductor device shown in FIG. 4;

FIG. 6 is a plan view for explaining a method of manufacturing the semiconductor device shown in FIG. 4;

FIG. 7 is a cross sectional view showing the configuration of the semiconductor device in a modified second embodiment;

FIG. 8 is a plan view showing the configuration of the semiconductor device shown in FIG. 7;

FIG. 9 is a cross sectional view showing the configuration of a semiconductor device in a third embodiment;

FIG. 10 is a plan view showing the configuration of the semiconductor device shown in FIG. 9;

FIG. 11 is a cross sectional view showing the configuration of a semiconductor device in a fourth embodiment;

FIG. 12 is a cross sectional view showing the configuration of a semiconductor device in a modified first embodiment;

FIG. 13 is a cross sectional view showing the configuration of a conventional semiconductor device;

FIGS. 14(A) and 14(B) are cross sectional views showing the configuration of another conventional semiconductor device; and

FIGS. 15(A), 15(B) and 15(C) are cross sectional views showing the configuration of a typical semiconductor device.

### DETAILED DESCRIPTION OF THE PREFERRED EMBODIMENTS

Embodiments of the present invention will now be explained with reference to the attached drawings. It is to be noted that the same reference numerals are respectively attached to common components in all the drawings, and their explanation will be omitted as occasion demands.

### First Embodiment

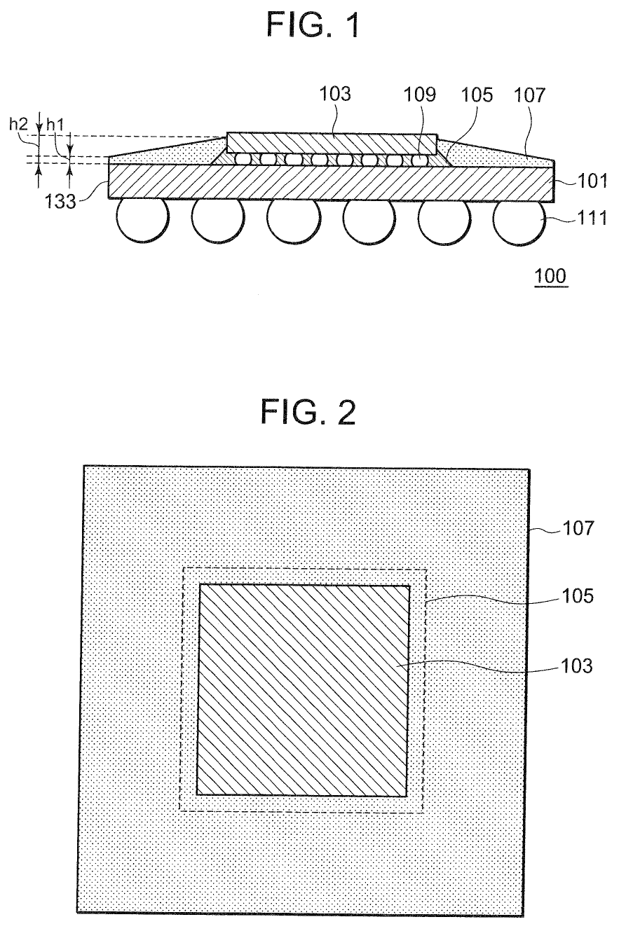

FIG. 1 is a cross sectional view showing the configuration of a semiconductor device of this embodiment. Moreover, FIG. 2 is a plan view showing the configuration of semiconductor device 100 shown in FIG. 1. In FIG. 2, bump electrode 109 and external connection electrode 111 are not shown.

The semiconductor device 100 shown in FIGS. 1 and 2 includes a first wiring substrate (package substrate 101), a first semiconductor element (first semiconductor chip 103) connected, through flip-chip bonding, to an element (chip) mounting surface of the package substrate 101, and a resin layer (underfill resin 105, outer peripheral layer 107) for coating substantially the entire chip mounting surface of the package substrate 101 including the area where the first semiconductor chip 103 is mounted.

The package substrate 101 is a wiring substrate on which a predetermined wiring structure and electrodes are provided.

Since material of the package substrate 101 is resin such as organic resin, etc. in a practical sense, and is constituted by resin material having insulating property, it can also be said from such a viewpoint that the package substrate 101 is an insulating substrate having a predetermined wiring structure and electrodes.

Moreover, in the case where an organic resin substrate is used as the package substrate 101, the organic resin substrate is caused of the configuration in which, for example, built-up (not shown) and solder resist (not shown) are laminated in order recited from the inside of the substrate toward the outside on both surfaces of core (not shown). More specifically, the package substrate 101 is a substrate in which solder resist, built-up, core, built-up and solder resist are laminated in order from the lower side.

As resin component of core, for example, BT resin or epoxy resin, may be used. Moreover, base material of core such as glass is employed. Further, the built-up is caused to be of the configuration including, for example, a wiring layer formed by plating or etching, epoxy resin and filler, etc. The number of built-up layers laminated at respective surfaces of the core may be determined as occasion demands in accordance with design of the semiconductor device 100. Moreover, as solder resist, for example, photosensitive resin may be used. More specifically, as the photosensitive resin, photosensitive epoxy resin may be used.

Moreover, the package substrate 101 may be also a coreless substrate having no core. Further, the package substrate 101 may be a substrate having flexibility such as tape substrate, etc. By using such a substrate, it is possible to securely realize thin structure of the package substrate 101.

From a viewpoint of realizing thin structure of the entirety of package, the thickness of the package substrate 101 is preferably 560 μm (0.56 mm) or less, and is more preferably 300 μm or less. Moreover, the lower limit of the thickness of the package substrate 101 is not particularly limited, but is caused to be 50 μm or more from a viewpoint of further reliably obtaining the strength of the package substrate 101.

The first semiconductor chip 103 is connected, through flip-chip bonding, by the bump electrode 109, on the chip mounting surface of the package substrate 101. The first semiconductor chip 103 includes a semiconductor substrate such as silicon substrate, etc., and a predetermined semiconductor element such as transistor, etc. provided on the element mounting surface.

The surface facing to the package substrate 101 of the first semiconductor chip 103 is coated by an underfill resin 105 except for the area where a bump electrode is formed. Moreover, the first semiconductor chip 103 has a surface facing the package substrate 101, and a reverse surface thereof which is not coated by the underfill resin 105 and an external peripheral layer 107.

Although the thickness of the first semiconductor chip 103 is not particularly limited, it caused to be 200 μm or less.

In this embodiment and the embodiments described below, explanation will now be given by taking, as an example, the case where the resin layer for coating the chip mounting surface of the package substrate 101 includes a first resin (underfill resin 105) provided within the area where the first semiconductor chip 103 is mounted, and a second resin (outer peripheral layer 107) provided at the periphery of the underfill resin 105. In this case, the resin layer may be constituted by the same material on substantially the entire chip mounting surface.

The underfill resin 105 is filled within the area between the chip mounting surface of the package substrate 101 and the surface on which the first semiconductor chip 103 is formed. In this embodiment and the embodiments described below, there is illustrated the structure in which the underfill resin 105 is provided from the region between the package substrate 101 and the first semiconductor chip 103 toward a portion of the side surface of the first semiconductor chip 103.

As material of the underfill resin 105, for example, epoxy resin is employed. Moreover, from a viewpoint of further reducing warp taking place at the assembling process, it is preferable that the linear expansion coefficient within the temperature range from 25° C. of material of the underfill resin 105 to glass transition temperature is larger than linear expansion coefficient of the package substrate 101.

Moreover, as material characteristic of the underfill resin 105, for example, the glass transition point temperature is 70° C. or more in more practical sense. Moreover, it is desirable that the thermal expansion coefficient having glass transition point temperature of 25° C. or more of the underfill resin 105 is, for example, within the range from 25 ppm/° C. to 35 ppm/° C.

The outer peripheral layer 107 is a resin layer provided in a manner continuous to the underfill resin 105 on the chip mounting surface of the package substrate 101. The entire surface of the chip mounting surface of the package substrate 101 is directly coated by the outer peripheral layer 107 or the underfill resin 105. The underfill resin 105 and the outer peripheral layer 107 are provided in a manner in contact with the package substrate 101 substantially on the entire chip mounting surface.

The outer peripheral layer 107 is provided from the side direction of the chip mounting region of the package substrate 101 toward the upper part of the end part of the package substrate 101. The outer peripheral layer 107 rise up toward the side surface of the first semiconductor chip 103 to coat at least a portion of the side surface of the first semiconductor chip 103. The thickness of the outer peripheral layer 107 at the side surface of the first semiconductor chip 103 is h2.

A side surface 133 of the semiconductor device 100 includes a side surface of the package substrate 101, and an end face of the outer peripheral layer above the side surface of the package substrate 101.

At the side surface 133 of the semiconductor device 100, the side surface of the package substrate 101 is exposed.

It is to be noted that in the case where the plane shape of the package substrate 101 is regular square or rectangular, it is needless to say that this surface includes four surfaces. Further, at the side surface 133 of the semiconductor device 100, the end surface of the outer peripheral layer 107 having a predetermined thickness is exposed.

Moreover, it is sufficient that the thickness h1 at the end face part of the outer peripheral layer 107 at the side surface 133 is a thickness to an extent such that stress is securely produced on the entire surface including the end part of the package substrate 101, and is caused to be 10 μm or more in this example. Further, the side surface 133 of the semiconductor device 100 is a cross section formed by dicing, etc. at the manufacturing process. For this reason, the side surface 133 is substantially coplanar surface, and the side surface of the package substrate 101 and the side surface of the outer peripheral layer 107 are positioned within the same plane.

It should be noted that although expression of the side surface of the package substrate 101 is employed in the opening part of this phrase, if the meaning of the cross sectional surface is emphasized in place of the expression of the side surface, the expression of the end face of the package substrate 101 may be also employed.

In this embodiment and the embodiments described below, the thickness of the resin layer including the underfill resin 105 and the outer peripheral layer 107 within the semiconductor device 100 is larger than that of the side surface of the semiconductor device 100. Specifically, the thickness of the resin layer, i.e., the outer peripheral layer 107 in this example satisfies the relation expressed as h2>h1. Moreover, the thickness of the outer peripheral layer 107 is minimum at the end part of the package substrate 101 within the region from the end part of the package substrate 101 up to the side surface of the first semiconductor chip 103, and is maximum at the surface in contact with the side surface of the first semiconductor chip 103. The thickness of the outer peripheral layer 107 continuously increases from the end part of the package substrate 101 toward the side surface of the first semiconductor chip 103.

Moreover, h2 is less than height from the chip mounting surface of the package substrate 101 up to the upper surface of the first semiconductor chip 103 (the reverse surface of the element mounting surface). When such a configuration is employed, it is possible to further securely prevent an increase in the height of the device resulting from the provision of the outer peripheral layer 107.

The material of the outer peripheral layer 107 may be the same as the material of the underfill resin 105, or may be material different therefrom. Moreover, in the case where the underfill resin 105 and the outer peripheral layer 107 are constituted by the same material, they may be continuously integrally formed. Here, continuous integration means that they are integrally molded as a continuous body. Moreover, it is preferable to employ a structure which includes a single member, but does not include a connection part.

Moreover, from a viewpoint of further reducing warp taking place at assembling process of the semiconductor device 100, it is preferably that the linear expansion coefficient within the temperature range from 25° C. of material of the outer peripheral layer 107 up to the glass transition temperature is larger than that of the linear expansion coefficient of the package substrate 101.

An external connection electrode 111 is connected, i.e., bonded to the reverse surface of the chip mounting surface of the package substrate 101. The package substrate 101 is connected to a mounting board such as mother board, etc. through external connection electrodes 111.

The bump electrode 109 and the external connection electrode 111 are both bump electrode. These bump electrodes are constituted by conductive material such as metal, etc. Specifically, material of the bump electrode may be lead free solder. Moreover, the material of the bump electrode may be high temperature solder having a melting point higher than that of the lead free solder, or metallic bump such as Au, Cu, Ni, etc. Moreover, as an example of plural bump electrodes 109, both solder bump and Au bump may be used.

A method of manufacturing the semiconductor device 100 will now be explained.

First, a multiple substrate (not shown) including plural regions where the first semiconductor chip 103 is to be mounted, and first semiconductor chips 103 are prepared. Within the respective chip mounting regions of the multiple substrate, the first semiconductor chips 103 are connected, through flip-chip bonding, by plural bump electrodes 109 to the respective chip mounting regions of the multiple substrate. Thus, the package substrate 101 and the first semiconductor chip 103 are electrically connected by using the bump electrodes 109 in the state where the circuit surface of the first semiconductor chip 103 is positioned toward the substrate side.

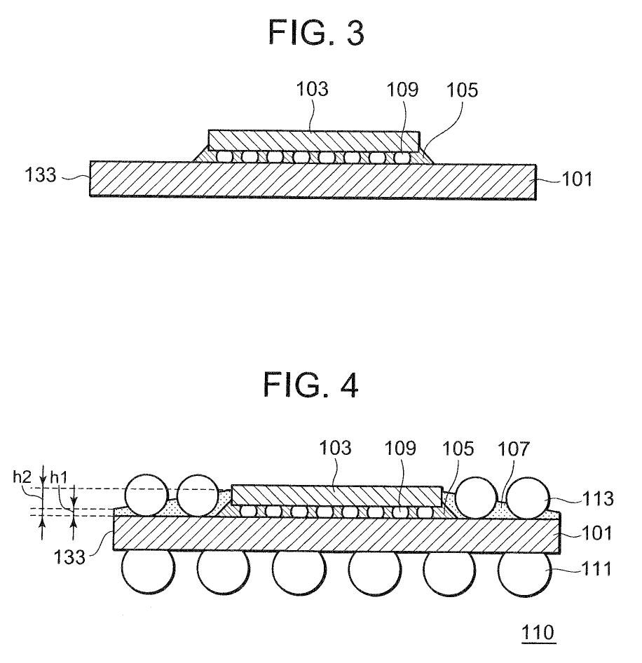

Next, the underfill resin 105 is filled, by making use of, for example, capillary phenomenon, within a gap between the first semiconductor chip 103 and the multiple substrate to seal the gap by the underfill resin 105. In this example, the underfill resin 105 may be delivered to predetermined regions (respective chip mounting areas) of the chip mounting surface of the multiple substrate in advance. Further, the underfill resin 105 is cured by heat. Thus, an intermediate structure shown in FIG. 3 is obtained.

In the intermediate structure of FIG. 3, the chip mounting surface side of the multiple substrate exhibits warp in convex form by tensile stress of the multiple substrate taking place resulting from thermal expansion coefficient difference between the first semiconductor chip 103 and the multiple substrate, or tensile stress of the underfill resin 105 taking place resulting from thermal expansion coefficient difference between the first semiconductor chip 103 and that of the underfill resin 105.

Subsequently, resin constituting the outer peripheral layer 107 is delivered to the entirety of the region except for the chip mounting region of the chip mounting surface of the multiple substrate. At this time, for example, resin in liquid form is dropped down to adjust supply quantity of resin and surface tension to thereby perform a control such that the height of the outer peripheral layer 107 maintains the relation expressed as h2>h1. Further, the outer periphery layer 107 is cured by heat. The outer peripheral layer 107 has a function to produce tensile stress due to curing contraction to warp the entirety of package in a concave form with the chip mounting surface being positioned upwardly.

It is to be noted that in the case where the underfill resin 105 and the outer peripheral layer 107 are constituted by the same material, resin may be delivered once to form the outer peripheral layer 107 along with formation of underfill.

Further, the multiple substrate is cut into segments along the dicing line to provide package substrates 101. At this time, the outer peripheral layer 107 having a predetermined thickness is exposed to the side surface, i.e., the cross sectional surface of the semiconductor device 100. Further, on the reverse surface of the chip mounting surface of the package substrate 101, there are formed solder balls, etc. as plural external connection electrodes 111 for connecting to the mounting board.

It should be noted that while explanation has been given by taking, as an example, the case where the multiple substrate is divided into fragments thereafter to form semiconductor balls, there may be collectively formed solder ball, etc. thereafter to cut them into fragments.

By the above-mentioned procedure, the semiconductor device 100 shown in FIGS. 1 and 2 can be obtained.

It is to be noted that while the example using multiple substrate is shown in the above-description, package substrates 101 fragmented in advance may be used. In this case, the outer peripheral layer 107 may be formed on the chip mounting surface of the package substrate 101 thereafter to connect plural external connection electrode 111 to the reverse surface thereof.

The advantages/effects of this embodiment will now be explained.

In this embodiment, resin layer including underfill resin 105 or the outer peripheral layer 107 is provided on substantially the entire surface except for the connection region of the bump electrode 109 of the chip mounting surface of the package substrate 101. By providing such a resin layer, it is possible to warp the package substrate 101 in a concave form by contraction force of resin in the case where the first semiconductor chip 103 is positioned upwardly. Thus, there is improved coplanarity of the package ordinarily warped in convex form with the chip mounting surface being positioned upwardly. Namely, in this embodiment, it is possible to produce, on the package substrate 101 entire surface, contraction stress in a direction opposite to that of warp taking place at the package substrate 101 by the underfill resin 105 and the outer peripheral layer 107. For this reason, warp taking place at the package substrate 101 can be cancelled and reduced. Thus, coplanarity of the package substrate 101 can be improved. Thus, staking yield of the package stacking process can be improved.

Moreover, in this embodiment, the underfill resin 105 or the outer peripheral layer 107 is provided on the entire element mounting surface of the wiring substrate, thereby making it possible to suppress stress concentration resulting from the fact that the bimetal effect is locally exhibited, and crack followed thereby.

Moreover, since the outer peripheral layer 107 having a predetermined thickness exists on the side surface of the semiconductor device 100, it is possible to further securely produce stress in a direction to warp the package substrate 101 in a concave form in the in-plane direction of the package substrate 101.

Further, the height of the outer peripheral layer 107 is caused to have the relation expressed as h2>h1, thus making it possible to provide the configuration in which according as the distance up to the package end becomes large when viewed from the package end side, a force to warp the package substrate 101 in an concave form becomes small. Thus, it is possible to prevent peeling between the outer peripheral layer 107 and the package substrate 101 resulting from the fact that stress concentrates on the package end part or a part in the vicinity thereof. Thus, the reliability of the semiconductor device 100 can be improved.

In addition, since according as the distance from the chip end to the package end becomes large when viewed from the package end side, the rigidity of the package by the outer peripheral layer 107 becomes lower, it becomes possible to have a flexible structure to only absorb difference of z-displacement in a substrate normal direction due to thermal expansion coefficient difference.

From the fact as stated above, in accordance with this embodiment, high reliability flip-chip BGA (Ball Grid Array) structure oriented to package-on-package can be provided.

Moreover, in the semiconductor device 100, since the reverse surface of the element mounting surface of the first semiconductor chip 103 is not coated by resin, it is possible to thin the thickness of the entirety of the semiconductor device.

Further, in this embodiment, the first semiconductor chip 103 is connected, through flip-chip bonding, to the package substrate 101, thereby making it possible to suppress increase in the chip size with respect to increase of I/O as compared to the structure using wire-bonding of “Successive Massproduction of Semiconductor Package” [online] Semiconductor Industrial Newspaper dated Jan. 18, 2006 [Retrieve Jul. 18, 2006] Internet <URL: http://www.semicon-news.co.jp/news/htm/sn1673-j.htm>, etc.

As stated above, in this embodiment, since coplanarity of the package substrate 101 can be enhanced without increasing the thickness of the package substrate 101, compatibility between realization of thin structure of the substrate and realization of thin structure of components can be realized. Thus, such semiconductor device can be suitably used also within the field where realization of thin structure and miniaturization of the entirety of package are required, such as, for example, mobile telephone, etc.

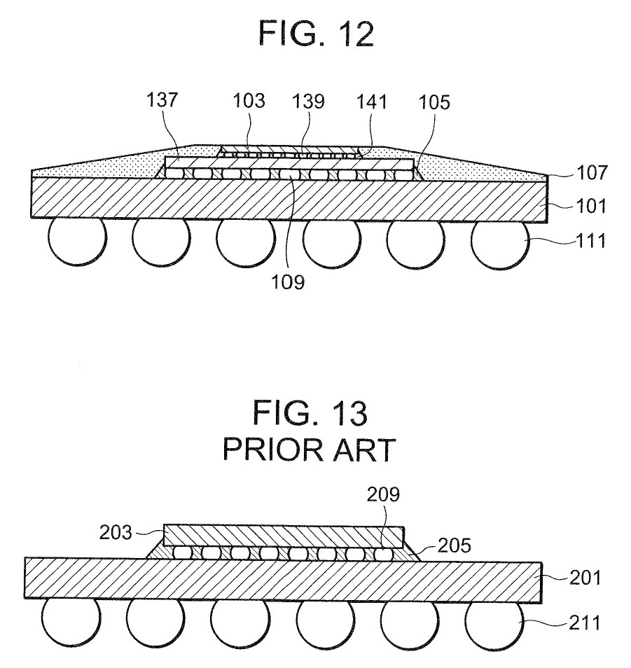

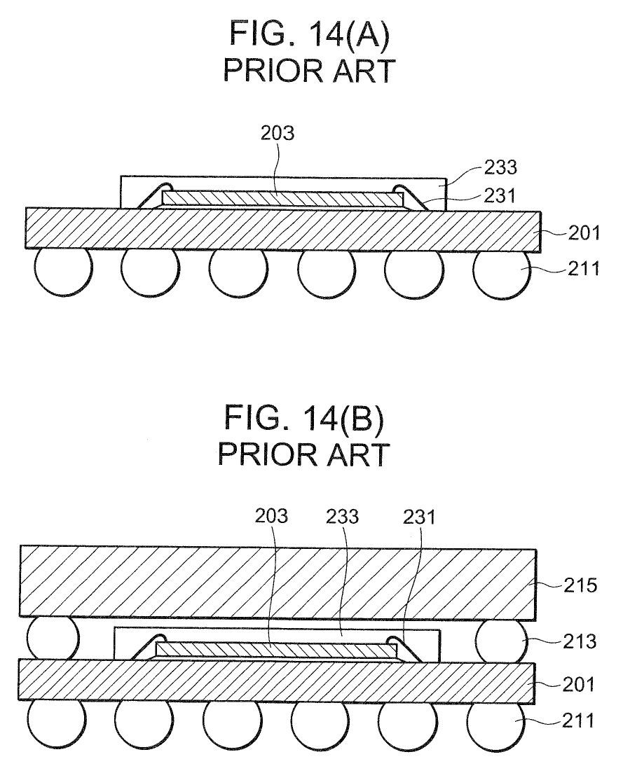

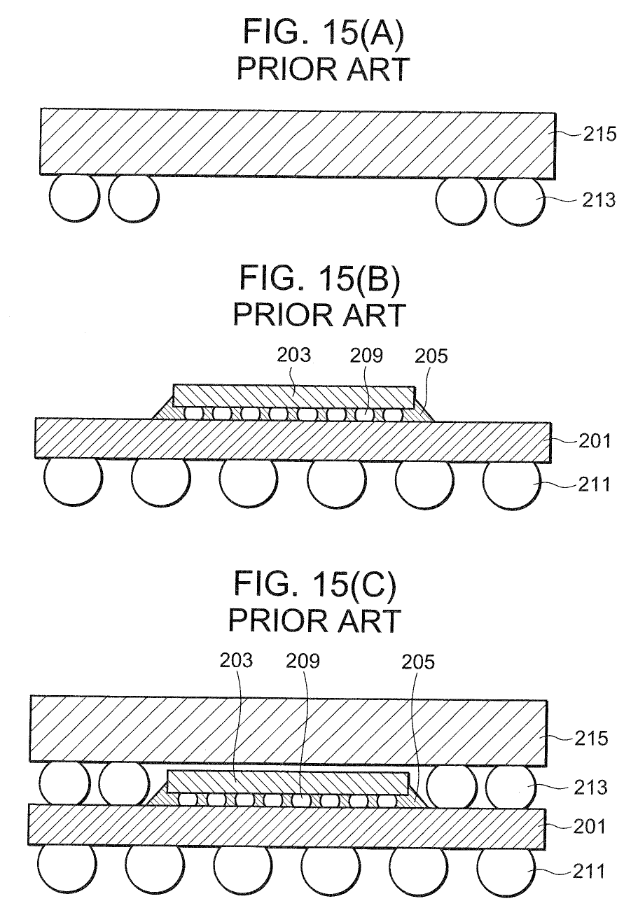

As shown in FIG. 12, in mounting the first semiconductor chip 103 onto package substrate 101, it may be flip-chip connected through interposer, etc. particularly silicon interposer 137 consisting of silicon substrate. Namely, silicon interposer 137 is mounted on package substrate 101 through bump electrodes 109, and first semiconductor chip 103 is mounted on the silicon interposer 137 through other bump electrodes 139, etc. Saying from such a point of view, it can be said that the semiconductor device 100 may be constituted as not only the semiconductor chip, but also the semiconductor package.

Here, the semiconductor chip refers to a chip in which transistor, resistor, capacitor and/or diode, etc. are formed as a circuit through wiring by conductive material on a semiconductor substrate. The semiconductor package refers to a package in which wiring members, etc. (e.g., interposer, wiring substrate, lead frame, etc.) for external terminal taking-out purpose are added to semiconductor chip, and refers to package including both package having armor such as mold armor, etc. and package having no armor. This commonly applies to the entirety of this specification.

It is to be noted that since both the semiconductor chip and the semiconductor package which has been explained above both include semiconductor element, in the case they are commonly referred to, such semiconductor package is referred to as semiconductor element in this specification. Accordingly, in this embodiment, it can be said that the semiconductor element is connected, through flip-chip bonding, to the element mounting surface of the first wiring substrate.

Returning to FIG. 12, additional explanation will be given. The silicon interposer 137 includes electrodes penetrated through the silicon interposer and internal wiring layer, etc., and is used for rearrangement of connection terminals, etc.

Moreover, in this instance, the underfill resin 105 is filled between the silicon interposer 137 and the bump electrode 109, etc. as shown in FIG. 12.

In FIG. 12, the underfill resin 105 filled between the package substrate 101 and the silicon interposer 137, and underfill resin 141 filled between the first semiconductor chip 103 and the silicon interposer 137 may be the same material, or different materials. Moreover, similarly to the underfill resin 105, the underfill resin 141 may be the same material as that of the outer peripheral layer 107, or may be material different therefrom.

Moreover, there is illustrated the configuration in which the silicon interposer 137 is embedded within the outer peripheral layer 107. When such a configuration is employed, the manufacturing stability of the semiconductor device can be further improved. It is to be noted that there is no particularly limitation in presence/absence of the outer peripheral layer 107 on the upper part of the chip mounting surface of the silicon interposer 137, and it is only required that at least the entire element mounting surface of the package substrate 101 is coated by resin, and the reverse surface of the semiconductor chip 103 is exposed from the outer peripheral layer 107.

Further, as shown in FIG. 12, bump electrodes 139 are disposed so that, for example, they are smaller than the bump electrodes 109 and the density thereof is higher than that.

When miniaturization of semiconductor chip will be increasingly advanced in future, it is considered that in the case where attempt is made to directly connect, through flip-chip bonding, the bump electrode such as bump electrode 109, etc. and the first semiconductor chip 103, dimensional miss-matching takes place, and unnecessary outer shape dimensions are thus required for the first semiconductor chip 103 so that loss may take place in point of cost. However, as shown in FIG. 12, by making connection through the silicon interposer 137, the connecting surface to the package substrate 101 is connected to bump electrodes 109 disposed at a low density, and the connecting surface to the semiconductor chip 103 can be connected to the bump electrodes 139 disposed at a high density. Thus, dimensional miss-matching is eliminated to also have ability to comply with such problem.

Further, an interposer substrate having a suitable thickness about 50 μm to about 200 μm as an example although there is no particularly contraction, and a semiconductor chip having the thickness of about 50 μm to 200 μm are used, thereby making it possible to comply with the previously described problems.

In the embodiment described below, the point different from that of the first embodiment will be mainly explained.

### Second Embodiment

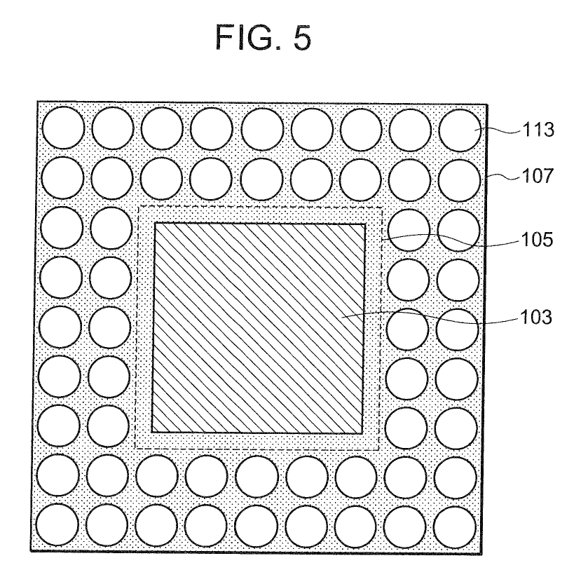

FIG. 4 is a cross sectional view showing the configuration of a semiconductor device of the second embodiment. Moreover, FIG. 5 is a plan view showing the configuration of a semiconductor device 110 shown in FIG. 4. In FIG. 5, bump electrode 109 and external connection electrode 111 are not shown.

The semiconductor device 110 shown in FIGS. 4 and 5 is similar to the semiconductor device 100 shown in FIG. 1 in the fundamental configuration, but differs from the latter in that plural bump electrodes for package connection (substrate connecting electrodes 113) are embedded within the outer peripheral layer 107.

Moreover, also in the case of the second embodiment and the embodiments succeeding thereto, it is a matter of course that the first semiconductor chip 103 may be mounted on package substrate through interposer, etc. similarly to the first embodiment. However, since explanation becomes complicated, the case including no interposer, etc. is illustrated.

The substrate connection electrode 113 is connected, i.e., bonded to the chip mounting surface of the package substrate 101 in the state where a portion of the substrate connection electrode is embedded within the outer peripheral layer 107. The substrate connection electrode 113 is connected to electrodes (not shown) provided on the package substrate 101.

On the substrate connection electrode 113, as described later, there are mounted, for example, semiconductor device including one semiconductor chip or more, electronic components, insulating substrate such as organic substrate, etc., and/or wiring substrate. In this case, there may be mounted plural semiconductor devices or electronic components.

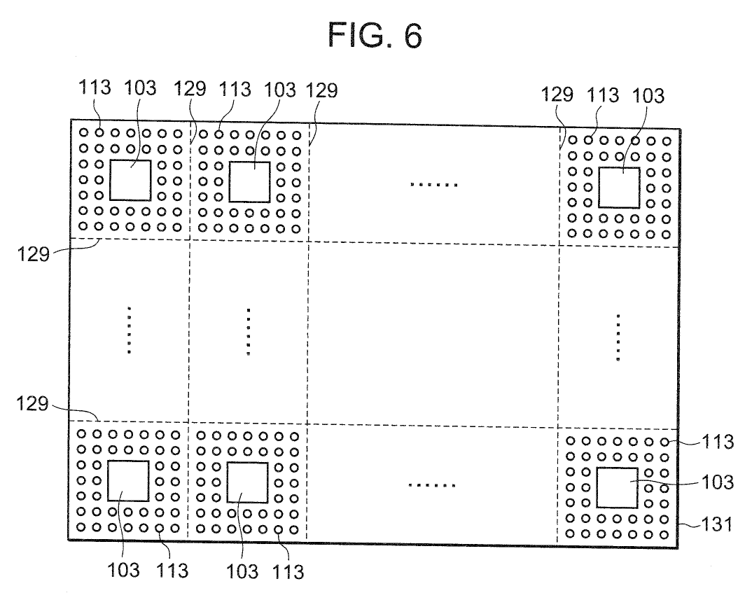

ON the chip mounting surface of the package substrate 101, the plural substrate connection electrodes 113 are provided, in a manner to surround the outer circumference of the chip mounting region, around the mounting region of the first semiconductor chip 103. Although the planar arrangement of the substrate connection electrodes 113 is not particularly limited, the planar arrangement is caused to be in regular lattice form as shown in FIG. 6 which will be described later, for example.

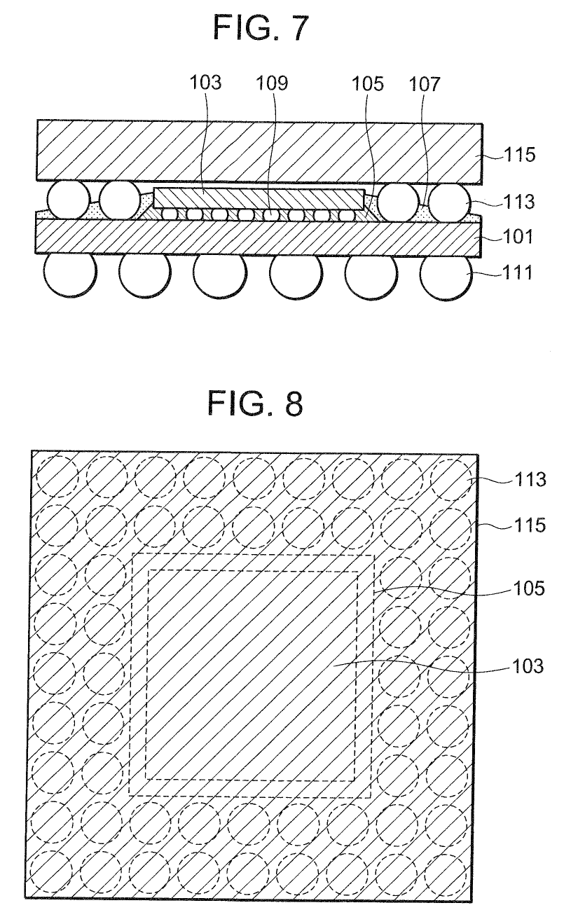

As described below with reference to FIG. 7, the substrate connection electrode 113 is an electrode for obtaining an electric connection to package stacked above the first semiconductor chip 103. For this reason, the height of the substrate connection electrode 113 from the chip mounting surface of the package substrate 101 is larger than the height of the chip mounting region. Namely, the height of the substrate connection electrode 113 is larger than the height from the chip mounting surface of the package substrate 101 up to the reverse surface (upper surface) of the element formation surface of the first semiconductor chip 103.

In this example, as material of the substrate connection electrode 113, there may be used material previously described as material of the bump electrode 109 or the external connection electrode 111 in the first embodiment.

Moreover, although the function of the first semiconductor chip is not particularly limited, the first semiconductor chip may be constituted by semiconductor chip including, for example, CPU (Central Processing Unit) or logic circuit, and serving as, as a main part, functional part, so-called logic part governing function or instruction of portable terminal equipment. In this case, semiconductor chip connected through the substrate connection electrode 113, and semiconductor package having, for example, function of memory, etc. may be also connected.

A method of manufacturing the semiconductor device 110 will now be explained. The semiconductor device 110 can be manufactured in conformity with the method of manufacturing the semiconductor device 100.

FIG. 6 is a plan view for explaining the method of manufacturing the semiconductor device 110 shown in FIGS. 4 and 5.

As shown in FIG. 6, plural first semiconductor chips 103 are connected, through flip-chip bonding, to a predetermined region of a multiple substrate 131. Further, underfill resin 105 (not shown in FIG. 6) is filled within a gap between the first semiconductor chips 103 and the multiple substrate 131.

Subsequently, plural substrate connection electrodes 113 are mounted along the outer peripheries of the respective package substrates 101 on the chip mounting surface of the multiple substrate 131. For example, in the case where the substrate connection electrodes 113 are caused to be solder bump, those substrate connection electrodes 113 may be formed by reflow process.

Further, resin in a liquid form serving as the outer peripheral layer 107 is dropped onto the chip mounting surface of the multiple substrate 131 to thermally cure such resin to form outer peripheral layer 107. Also in this embodiment, supply quantity of resin is adjusted so that the relation expressed as h2>h1 holds.

It is to be noted that in the case where the underfill resin 105 and the outer peripheral layer 107 are constituted by the same material, substrate connection electrodes 113 may be formed without providing the underfill resin 105 after the first semiconductor chip 103 is mounted thereafter to supply resin in a liquid form to thereby form, by a process collectively performed, underfill resin 105 and outer peripheral layer 107.

Thereafter, similarly to the first embodiment, the multiple substrate 131 is cut, along a dicing line 129 so that it is fragmented into respective package substrates 101 each having side surface 133. Moreover, an external connection electrode 111 is formed on the reverse surface of each package substrate 101.

By the above-mentioned procedure, the semiconductor device 110 shown in FIGS. 4 and 5 is provided.

It should be noted that semiconductor device 110 shown in FIGS. 4 and 5 may be formed thereafter to further stack semiconductor package or semiconductor chip, i.e., semiconductor element on the upper part of the substrate connection electrode 113.

FIG. 7 is a cross sectional view showing the configuration of such a semiconductor device. Moreover, FIG. 8 is a plan view showing the configuration of the semiconductor device shown in FIG. 7. In FIG. 8, package substrate 101, bump electrode 109 and external connection electrode 111 are not shown.

In FIG. 7, a second semiconductor element (semiconductor package 115) is provided on the substrate connection electrode 113 of the semiconductor device 110 shown in FIGS. 4 and 5. The semiconductor package 115 refers to a package in which wiring member for external terminal taking-out purpose etc. for example, interposer, wiring substrate or lead frame, etc. is added to the semiconductor chip as previously described, and refers to a package including armor such as mold armor, etc., or a package including no armor. The semiconductor package 115 is provided such that the semiconductor package 115 faces the chip mounting surface of the package substrate 101. Moreover, the first semiconductor chip 103 is disposed between the package substrate 101 and the semiconductor package 115.

It is to be noted that semiconductor chip may be provided on substrate connection electrode 113 in place of the semiconductor package 115 as previously described although not shown.

In this embodiment, on the chip mounting surface of the package substrate 101, there are provided plural substrate connection electrodes 113 functioning as a terminal connection to semiconductor device stacked on the upper part thereof. However, on the chip mounting surface of the package substrate 101, substantially the entire surface thereof is coated by the underfill resin 105 and the outer peripheral layer 107 except for the connecting part of the substrate connection electrode 113 and the bump electrode 109. For this reason, also in this embodiment, advantages/effects similar to those of the first embodiment can be provided.

Further, in this embodiment, warp of the package substrate 101 is reduced by contractive stress of the outer peripheral layer 107. For this reason, yield at the package stacking process for providing the structure shown in FIG. 7 can be improved. Moreover, also in the case where semiconductor device 110 (FIGS. 4 and 5) before stacking is mounted on mounting board (not shown) thereafter to provide package staked structure (FIG. 7), since warp quantity of the package substrate 101 is reduced by contractive stress of the outer peripheral layer 107, mounting process of stacked package for providing the structure shown in FIG. 7 becomes easy.

Moreover, also in this embodiment, there is provided the configuration to satisfy the relation expressed as h2>h1 with respect to the height of the outer peripheral layer 107 so that according as the distance up to the package end becomes large, variable quantity in a height (thickness) direction can become large. Thus, it becomes possible to absorb displacement difference based on thermal expansion coefficient difference between upper and lower packages taking place after stacking of package. Thus, long lifetime until breakage of the substrate connection electrode 113 can be realized.

Further, there is provided the configuration to satisfy the relation expressed as h2>h1 with respect to the outer peripheral layer 107 so that volume exposed from the outer peripheral layer 107 of the substrate connection electrode 113 becomes large as compared to the case where the relation expressed as h1=h2 is selected. For this reason, volume of the electrode contributing to connection becomes large in stacking the semiconductor package 115. Thus, improvement in yield at the package stacking process can be realized.

In addition, in this embodiment, attachment height of the semiconductor package 115 stacked on the package substrate 101 does not undergo the influence of supply of the outer peripheral layer 107. For this reason, there is no increase in height of the entirety of the device resulting from provision of the outer peripheral layer 107. Thus, there is provided further suitable configuration in miniaturization of the entirety of the device.

### Third Embodiment

While there is illustrated, in the second embodiment, the configuration in which semiconductor package 115 or semiconductor chip, i.e., semiconductor element is mounted on substrate connection electrode 113 (FIG. 7), any other wiring substrate may be mounted on the substrate connection electrode 113. In this embodiment, an example of such a configuration is shown.

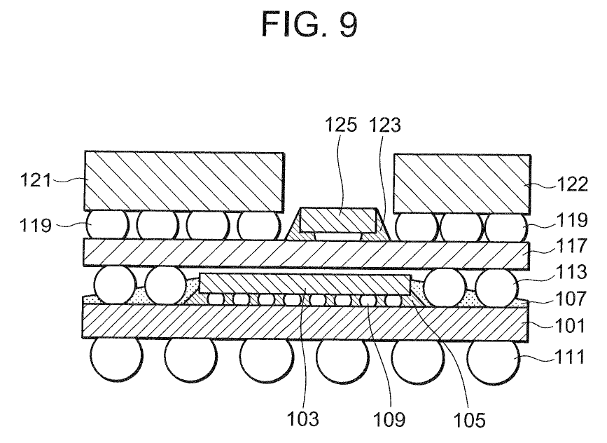

FIG. 9 is a cross sectional view showing the configuration of a semiconductor device of this embodiment.

The semiconductor device shown in FIG. 9 is similar to the semiconductor device shown in FIG. 7 in the fundamental configuration, but differs from the latter in that second wiring substrate (interposer 117) is provided on substrate connection electrode 113.

The interposer 117 used as the second wiring substrate is provided such that the interposer 117 faces the chip mounting surface of the package substrate 101. The interposer 117 is a connection substrate for electrically connecting package substrate 101 and semiconductor element or electronic components, etc. above the interposer 117, and includes substrate, and penetrated electrode structure (not shown) provided within the substrate. The substrate may be constituted as an insulating resin substrate, for example, organic resin, or may be constituted by silicon substrate having insulating property.

It is to be noted that the second wiring substrate refereed to here may be a substrate including wiring layer and terminal connection electrodes only on the surface layer of the substrate.

Moreover, the thickness of the interposer 117 is not particularly limited, but is caused to be 200 μm or less from a viewpoint of realization of thin structure of the entirety of the device. Moreover, from a viewpoint of further sufficiently securing the strength of the interposer 117, the thickness of the interposer 117 is caused to be 50 μm or more.

Further, in FIG. 9, there is illustrated the case where the interposer 117 and the package substrate 101 have substantially the same shape, and the first semiconductor chip 103 is disposed between the interposer 117 and the package substrate 101. However, the plane shape and dimensions of the interposer 117 are not particularly limited. In addition, as illustrated here, the plane shapes of the interposer 117 and the package substrate 101 are not limited to regular square, but may be rectangle.

In FIG. 9, a third semiconductor element (third semiconductor element 122) is connected, through flip-chip bonding, to the reverse surface of the upper surface of the interposer 117, i.e., the surface facing the package substrate 101. While there is illustrated in this embodiment an example where one electronic component and two semiconductor chips are mounted on the upper surface of the interposer 117, semiconductor chips, semiconductor packages or electronic components such as capacitor, coil and resistor, etc. which are arbitrary in number and kind may be mounted on the interposer 117. Although particularly not limited, electronic component 125 in a chip form may be typically used.

In this example, second semiconductor element 121 and third semiconductor element 122 are mounted, through plural substrate connection electrodes 119, on the reverse surface of the surface facing the package substrate 101 of the interposer 117, i.e., the upper surface of the interposer 117. Moreover, electronic components 125 such as capacitor, etc. are connected to the upper surface of the interposer 117 by solder 123, etc.

In addition, the second and third semiconductor elements 121 and 122 are both supplied in a form as required depending upon shape of the semiconductor chip or shape of the semiconductor package, etc.

Here, for example, the second semiconductor element 121 may be constituted by memory such as DRAM, etc., and the third semiconductor element 122 may be constituted by non-volatile memory such as flash memory, etc. Moreover, as the electronic component 125 mounted therebetween, for example, chip capacitor may be used. In this case, the first semiconductor chip 103 may serve as, for example, logic part, CPU part and/or part like microcomputer of portable terminal equipment, and the memory part on the interposer 117 may be changed as occasion demands, thereby making it possible to realize long-range maintenance of function as the entirety of the semiconductor device.

Also in this embodiment, since warp of the package substrate 101 is suppressed similarly to the above-described embodiments, also in the case where wiring substrate such as interposer 117, etc. is stacked on the substrate connection electrode 113, and a predetermined semiconductor chip or package is further mounted on wiring substrate such as interposer 117, etc., it is possible to effectively suppress lowering of yield at the stacking process.

It should be noted that the wiring substrate may be both-sided wiring substrate in which wirings are made on both surfaces of core layer, or thin type stacked wiring substrate, etc. Moreover, the wiring substrate may be silicon interposer, etc. Material of the wiring substrate may be constituted by metallic conductive body, organic resin or silicon, etc.

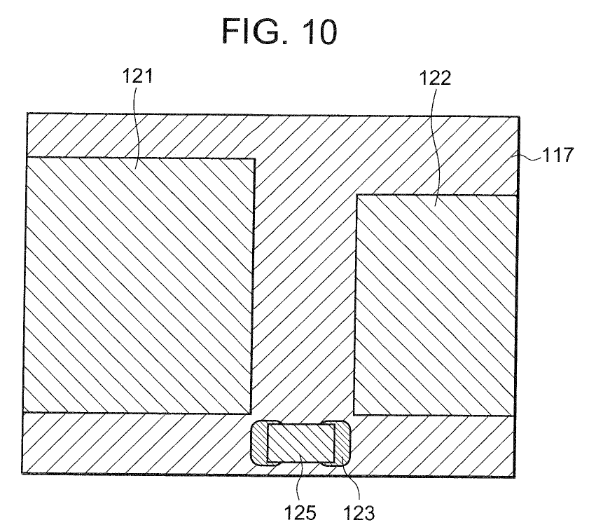

In addition, while there is illustrated in FIG. 9 the configuration in which second semiconductor element 121, electronic component 125 and third semiconductor element 122 are disposed within the same cross section, the planar arrangement of these components may be as shown in FIG. 10. FIG. 10 is a top view showing the semiconductor device of this embodiment. In FIG. 10, layer or layers above the interposer 117 in FIG. 9 are shown, and a portion or portions of members in FIG. 9 is or are not shown.

### Fourth Embodiment

While the reverse surface of the chip mounting surface is the mounting surface onto the mounting board in the above-described embodiments, the mounting surface onto the mounting board and the chip mounting surface may flush with each other. In this embodiment, an example of such a configuration is shown.

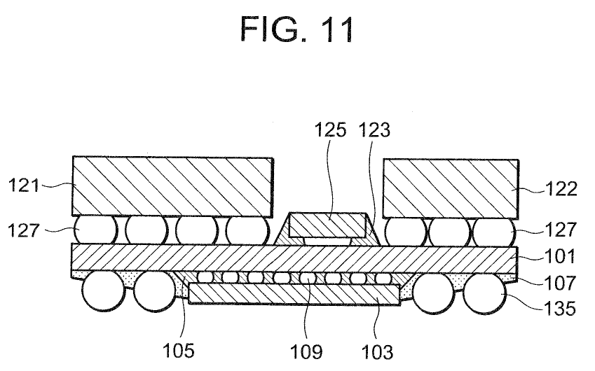

FIG. 11 is a cross sectional view showing the configuration of a semiconductor device of this embodiment.

In FIG. 11, the chip mounting surface of the package substrate 101 is a surface facing to mounting board (not shown) on which the package substrate 101 is mounted. The first semiconductor chip 103 is provided on the mounting surface onto the mounting board of the package substrate 101, and the first semiconductor chip 103 is disposed between the package substrate 101 and mounting board (not shown).

Moreover, on the lower surface of the package substrate 101, i.e., the chip mounting surface, similarly to the second embodiment (FIG. 4), there are provided first semiconductor chip 103, underfill resin 105, outer peripheral layer 107 and bump electrode 109. It should be noted that the substrate connection electrodes 113 for connecting to the semiconductor package 115, etc. are provided within the outer peripheral layer 107 in the semiconductor device 110 of FIG. 4, whereas external connection electrodes 135 to be connected to mounting board are embedded within the outer peripheral layer 107 in this embodiment. The package substrate 101 is connected to mounting board (not shown) such as mother board through the external connection electrodes 135.

The height of the external connection electrode 135 is larger than the height from the chip mounting surface of the package substrate 101 up to the backside (lower surface) of the element formation surface of the first semiconductor chip 103.

Moreover, in this embodiment, plural substrate connection electrodes 127 are provided on the upper surface of the package substrate 101, i.e., the backside of the chip mounting surface, and a second semiconductor element 121, an electronic component 125 and a third semiconductor element 122 are mounted on the substrate connection electrode 127 in the state where they are arranged in line within the plane. In addition, the electronic component is connected to the backside of the mounting surface of the package substrate 101 by solder 123.

Also in this embodiment, since warp of the package substrate 101 is suppressed, advantage/effects similar to those of the above-described embodiments can be provided.

It should be noted that while there is shown in FIG. 11, the configuration in which the second semiconductor element 121, the electronic component 125 and the third semiconductor element 122 are disposed within the same cross section, the plane arrangement of the second semiconductor element 121, the electronic component 125 and the third semiconductor element 122 may be as shown in FIG. 10 in the same manner as the third embodiment also in this embodiment.

While the embodiments of the present invention have been described with reference to the attached drawings, these embodiments are exemplary embodiments of the present invention, and various configurations except for the above may be therefore employed.

While there is illustrated in the above-described embodiments, for example, the case where the resin layer for coating the chip mounting surface of the package substrate 101 includes underfill resin 105 and outer peripheral layer 107, the resin layer may be constituted by the same material. Moreover, the outer peripheral layer 107 may be formed of one kind of resin, or may be formed of plural resins.

Moreover, there is particularly no limitation in a method of connecting electrode (not shown) provided on the package substrate 101 and electrode (not shown) provided on the first semiconductor chip 103. For example, such a connection method may be realized by either one of alloy connection by solder, metallic connection of Au and Au, alloy connection of Au and solder, connection based on contact between metals, and a method of connecting electrodes through conductive adhesive agent.

Further, the electric connection method between electrodes may be performed by, for example, heat treatment. Moreover, heat and load may be used in combination, or heat, load and ultrasonic wave may be used in combination.

In addition, while there are mainly illustrated in the above-described embodiments the case where the plane shape of a substrate including the package substrate 101, and a semiconductor element including first semiconductor chip 103 is regular square, these plane shapes are not limited to regular square, but may be rectangle, other square or any other shape.

What is claimed is:

1. A semiconductor device comprising:
a first wiring substrate;
a first semiconductor element mounted, through flip-chip bonding, on an element mounting surface of the first wiring substrate; and
a resin layer that coats substantially the entire element mounting surface of the first wiring substrate including an area where the first semiconductor element is mounted,
wherein the first semiconductor element has two opposite surfaces, one surface facing the element mounting surface of the first wiring substrate, the other surface being not coated by the resin layer.

2. The semiconductor device according to claim 1, wherein a side surface of the first wiring substrate and the resin layer having a predetermined thickness are exposed on a side surface of the semiconductor device.

3. The semiconductor device according to claim 2, wherein a thickness of the resin layer within the semiconductor device is thicker than a thickness of an end part of the semiconductor device.

4. The semiconductor device according to claim 1, wherein a material of the first wiring substrate is resin.

5. The semiconductor device according to claim 1, further comprising a bump electrode provided on the element mounting surface of the first wiring substrate, the bump electrode being disposed at the periphery of the first semiconductor element,
wherein a portion of the bump electrode is embedded within the resin layer.

6. The semiconductor device according to claim 5, further comprising a second semiconductor element mounted on the element mounting surface of the first wiring substrate through the bump electrode,
wherein the first semiconductor element is disposed between the first wiring substrate and the second semiconductor element.

7. The semiconductor device according to claim 5, further comprising:
a second wiring substrate mounted on the element mounting surface of the first wiring substrate through the bump electrode, the first semiconductor element being disposed between the first wiring substrate and the second wiring substrate; and
a third semiconductor element,
wherein the second wiring substrate has two opposite surfaces, one surface facing the first semiconductor element, and the other surface having the third semiconductor element mounted thereon, through flip-chip bonding.

8. The semiconductor device according to claim 5, further comprising a mounting board having the first wiring substrate mounted thereon,
wherein the element mounting surface of the first wiring substrate faces the mounting board, the bump electrode is an electrode connected to the mounting board, and the first semiconductor element is disposed between the first wiring substrate and the mounting board.

9. The semiconductor device according to claim 1,
wherein the first semiconductor element includes a semiconductor chip and an interposer substrate, and the semiconductor chip is connected through the interposer substrate on the element mounting surface of the first wiring substrate.

10. The semiconductor device according to claim 1,
wherein the resin layer includes:
a first resin provided within an area where the first semiconductor element is mounted; and
a second resin provided at the periphery of the first resin.

11. The semiconductor device according to claim 1, wherein the resin layer is constituted by the same material on the entire element mounting surface of the first wiring substrate.

12. The semiconductor device according to claim 1,
wherein the thickness of the first wiring substrate is 0.56 mm or less.

13. The semiconductor device according to claim 1,
wherein a thermal expansion coefficient of the resin layer is larger than a thermal expansion coefficient of the first wiring substrate.

14. A semiconductor device comprising a wiring substrate having a chip mounting area and a peripheral area surrounding the chip mounting area, a semiconductor chip mounted on the chip mounting area, and an outer resin coating the peripheral area of the wiring substrate.

15. The semiconductor device as claimed in claim 14, further comprising an underfill resin intervening between the semiconductor chip and the chip mounting area.

16. The semiconductor device as claimed in claim 14, wherein the semiconductor chip has a first main surface facing the chip mounting area and a second main surface opposing to the first main surface, the second main surface of the semiconductor chip being free from being coated by the outer resin.

17. The semiconductor device as claimed in claim 14, wherein the outer resin coats the peripheral area with a nonuniform thickness.

18. The semiconductor device as claimed in claim 17, wherein a portion of the outer resin near to the chip mounting area is larger in thickness than a portion of the outer resin far from the chip mounting area.
